(19) United States
(12) Patent Application Publication
(10) Pub. No.: US 2026/0227107 A1
(43) Pub. Date: Aug. 6, 2026

(54) Redundantly pumped two-phase heat transfer loop

(71) Applicant: CALYOS, Charleroi (BE)

(72) Inventor: Vincent Dupont, Auderghem (BE)

(73) Assignee: CALYOS, Charleroi (BE)

(21) Appl. No.: 19/531,364

(22) Filed: Feb. 5, 2026

(30) Foreign Application Priority Data
Feb. 6, 2025 (FR) 2501212

(51) Int. Cl. F25B 41/40

(52) U.S. Cl. CPC F25B 41/40

(57) ABSTRACT

A heat transfer system (100) comprising a main circuit (10) in a closed loop, comprising a predefined quantity of refrigerant fluid, a cooling exchanger (5) coupled to a cold source, to remove heat and subcool the fluid, a pump (1) on a branch (14) parallel to the main circuit, to impart a liquid circulation in the main circuit according to the circulation direction (F), an intermediate housing (3) placed in series on the main circuit, having three or four ports, with a liquid inlet and outlet and a vapor inlet, an evaporator assembly (2) arranged as a bypass of the main circuit with an inlet line (21), an evaporator (20) including a porous capillary pumping element (22) coupled to a hot source to be cooled, at least one outlet line (25) with an ejection nozzle (26), which injects the fluid in a mainly vapor phase into the intermediate housing.

The invention relates to heat transfer systems and more particularly to two-phase cooling loops. This type of system is used to cool various devices and in particular to cool one or more processors of an electronic board.

It is known from the prior art to advantageously use the circulation of a two-phase fluid (also called “refrigerant fluid” in the trade) with an evaporator and a condenser, phase changes making it possible to efficiently transport heat from one point to another. It is known to use this type of system to cool electronic boards, in particular server boards in a data center.

However, the systems in question are also intended to be used in embedded systems, for example, in automotive, rail, or aeronautical embedded systems.

Note that the heat transfer systems proposed here can also be used as anti-icing heating systems in an aircraft (to avoid ice at the wing leading edge and/or at the engine air intake) or for other heat transfer applications.

In a first known manner, the circulation of the working fluid in the loop can be generated by a mechanical pump. In a second manner also known, the circulation of the working fluid in the loop can be obtained by a thermosiphon effect, using the gravitational force of the Earth. Finally, in a third manner also known, the circulation of the working fluid in the loop can be obtained by a capillary pumping effect provided by a porous wick, which is a solution particularly relevant for space applications and/or in microgravity.

Note an excellent efficiency of the pump solution in nominal operation; however, regarding the solution involving a mechanical pump, it can happen that the pump in question suffers damage and/or fails. The occurrence of a pump failure implies stopping the circulation of the fluid and, consequently, an interruption of the cooling function.

The second and third solutions are based on a passive operating principle, without the need for active pumping i.e. without moving hardware elements.

But regarding the solution involving a thermosiphon effect, the efficiency of the solution depends on the orientation of the respective portions of the fluid circuit and the respective positions of the evaporator and the condenser.

And regarding the solution involving a capillary pumping effect, performance depends on the balance between pressure losses in the circuit and capillary suction pressure.

Thus, it turns out that each of the above solutions has its own advantages and disadvantages.

The inventors sought to propose a heat transfer system solution that combines the advantages of the above solutions and that minimizes their disadvantages. It is also desirable that the proposed solution can simultaneously cool several devices and/or several processors while limiting thermo-hydraulic instabilities.

For this purpose, a heat transfer system is proposed comprising:
a main circuit in a closed loop, comprising a predefined quantity of refrigerant fluid (two-phase), with a loop fluid circulation direction,
at least one cooling exchanger, comprising a portion of the main circuit and a heat exchanger coupled to a cold source, to remove heat and subcool the liquid, to deliver subcooled liquid,
at least one pump arranged on a branch parallel to the main circuit, to impart a liquid circulation in the main circuit according to the loop circulation direction, with tapping and discharge at respective locations where the refrigerant is in the liquid phase,
at least one intermediate housing placed in series on the main circuit, having at least 3 ports, namely a liquid inlet, a liquid outlet, and a vapor inlet, the liquid inlet receiving the subcooled liquid coming from the cooling exchanger,
at least one evaporator assembly arranged as a bypass of the main circuit with at least one inlet line, tapping liquid fluid from the main circuit,
an evaporator including a porous capillary pumping element coupled to a hot source to be cooled, to be the site of a vaporization of the refrigerant fluid,
at least one evaporator outlet line having at least one ejection nozzle that injects the fluid in a mainly vapor phase into the intermediate housing via the vapor inlet according to the loop circulation direction.

Thanks to these arrangements, fluid circulation is imparted by the pump in normal operation, but if a pump failure occurs, then the injection of vapor from the outlet line of the evaporator assembly into the main circuit causes an entrainment effect by transfer of momentum. The vapor jet forms a driving effect for the main loop circuit (“jet pump”) and a forced circulation of the working fluid is obtained in the main loop, despite the fact that the mechanical pump no longer rotates.

It is noted that the pump being arranged on a parallel branch, even if its turbine (or more generally its moving element) is blocked, this does not prevent circulation of the fluid in the main loop. Even if performance is reduced by stopping the pump, there remains a substantial circulation of fluid in the main loop generated by the vapor ejection nozzle(s). Consequently, a pump failure does not prevent the loop from continuing to operate. When the system is installed on board a vehicle, the occurrence of a pump failure can lead to a reduction in performance but does not cause a total loss of the cooling function.

By contrast, if the pump were arranged in series on the main circuit, a pump failure would lead to a total stop of circulation and a total interruption of the cooling service.

The proposed solution thus advantageously benefits both from the thermal performance provided by forced circulation of the pump in combination with passive circulation induced by the outlet nozzles from the evaporators in the intermediate housing(s).

Moreover, depending on possible configurations, circulation in the loop can be favored by a thermosiphon effect, or conversely, circulation can be without assistance by a thermosiphon effect.

It is noted that the pump flow rate can remain moderate since only a portion of the total flow is diverted from the main circuit and, consequently, the electrical consumption of the pump motor can remain minimal. The pump flow rate can be chosen in an optimal range between a minimum value and a maximum value, which will be discussed later.

The fluid is essentially liquid in the main loop circuit and the cooling exchanger is a subcooling exchanger; this has the advantage of minimizing vapor pressure losses for low-pressure fluid circulation in the main loop circuit; the condensation of the vapor leaving the ejector takes place in the intermediate housing, e.g. in the portion of the main circuit immediately adjacent, downstream of the vapor injection point. The subcooling exchanger provides sufficient subcooling so that the liquid phase in the main circuit remains liquid even in the presence of parasitic thermal leaks and prevents cavitation in the pump. The advantage of having a main circuit essentially containing liquid is that system operation is only minimally affected by the accelerations to which it is subjected, for example, in a vehicle with changing directions and highly variable intensity, and that it makes it possible to use low-pressure fluids without causing prohibitive pressure losses.

Another advantage of having a main circuit essentially containing liquid is that distribution of liquid fluid inside a complex and highly three-dimensional shape is simpler than in a vapor phase or two-phase state where distribution would be impacted by tilts and accelerations (due to gravity or the vehicle).

The notion of subcooling designates cooling below the saturation temperature Tsat (liquid-vapor equilibrium temperature for the pressure prevailing in the circuit). In practice, the subcooled liquid leaving the cooling exchanger is at a temperature 5° C. to 10° C. lower than the saturation temperature Tsat.

In embodiments of the device according to the invention, it is possible optionally to use in addition one and/or the other of the following arrangements.

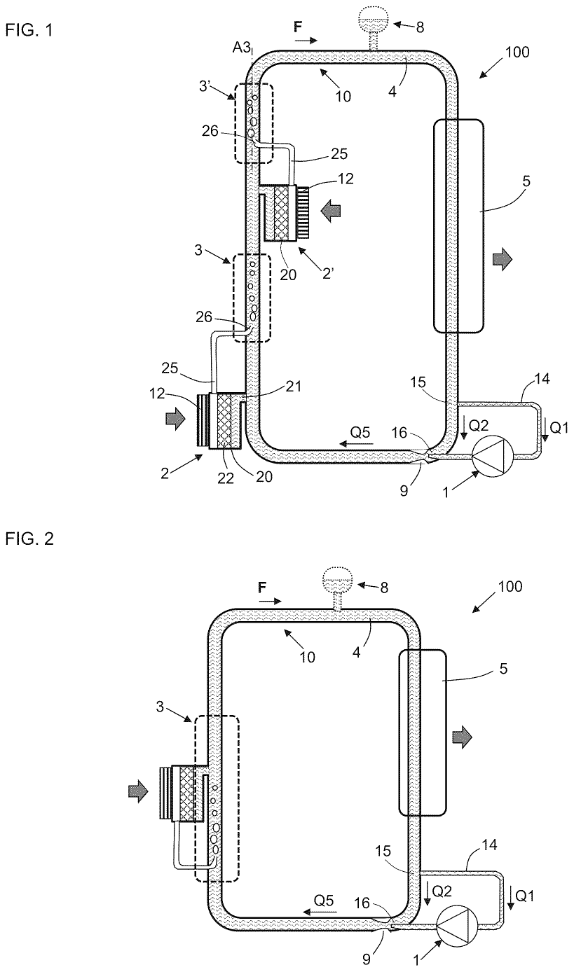

According to one embodiment, the pump is fed by subcooled liquid coming from the cooling exchanger and discharges further downstream a jet of liquid into the main circuit, upstream of the intermediate housing. This configuration is illustrated in FIGS. 1 to 3.

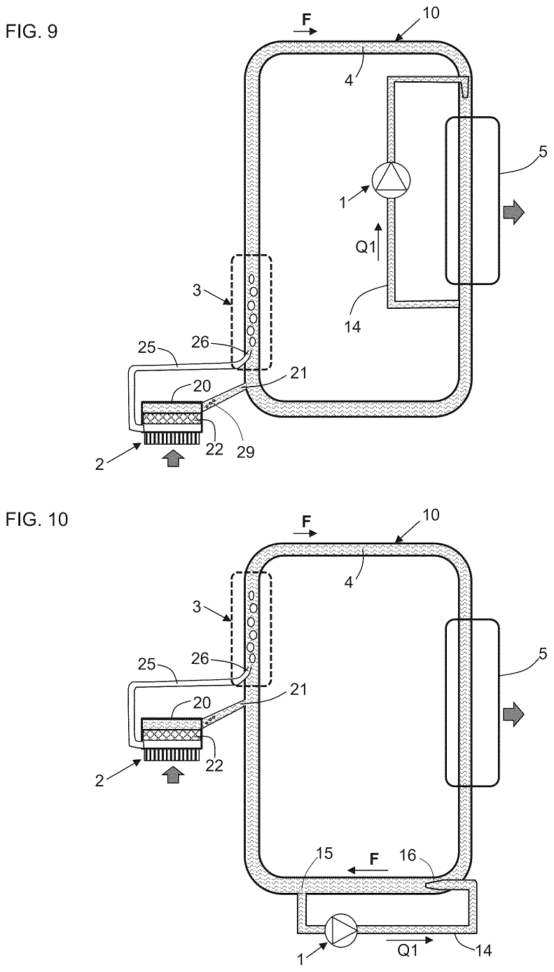

According to an alternative embodiment, the pump is fed by liquid tapped upstream of the cooling exchanger, and discharges liquid downstream of the cooling exchanger. This configuration is illustrated in FIG. 9.

According to an alternative embodiment, the pump is fed by liquid tapped at an intermediate point between the cooling exchanger and the intermediate housing, and discharges liquid upstream of said intermediate point. Remarkably, the discharge is upstream of the tapping point. This configuration is illustrated in FIG. 10.

According to one embodiment, the intermediate housing comprises an interior volume available to accommodate an excess of liquid, serving as a reservoir and expansion vessel.

Advantageously, the reservoir function then being housed inside at least one intermediate housing, it is not necessary in this case to provide a specific reservoir at a location on the main loop circuit.

According to one embodiment, the intermediate housing has an elongated shape with an axis in the local loop circulation direction.

It is noted that the axis A3 of the intermediate housing can be parallel to the local vertical direction, which favors the thermosiphon effect and the rise of possible vapor bubbles upward from the liquid inlet of the capillary evaporator(s), in addition to the entrainment effect by momentum.

According to other configurations, the axis A3 of the intermediate housing can be inclined relative to the vertical. It can even be horizontal.

According to one embodiment, the intermediate housing has a generally cylindrical shape. The intermediate housing is in this case easy to manufacture and has good pressure resistance without excessive mass. This configuration offers a good performance-to-cost ratio and makes it possible to make sealed joints in a well-controlled manner.

According to one embodiment, the intermediate housing comprises a guide tube that surrounds the ejection nozzle. The guide tube makes it possible to maximize local vapor condensation at the outlet of the ejection nozzle. The guide tube can be called a “confinement tube” or “constrained passage tube”.

According to one embodiment, one or more interior tubes can be provided in the intermediate housing, the tubes extending along the nozzle axis. Each tube can be arranged opposite a vapor ejection nozzle.

According to one embodiment, the change of state from the vapor phase to the liquid phase occurs essentially in the intermediate housing.

As the liquid circulating in the main loop is subcooled, it allows the vapor bubbles to be condensed on the fly inside the intermediate housing; this is then referred to as ‘direct’ condensation. The intermediate housing can thus be characterized as a direct-condensation housing. In nominal operation, the liquid outlet of the intermediate housing in practice does not contain refrigerant fluid bubbles in vapor form (it contains only liquid).

According to one embodiment, the system may comprise a source to be cooled in conductive thermal contact with a portion of piping of the main circuit.

As a result, direct condensation occurs at that location on the inner side of the piping wall, due to the temperature of the subcooled fluid being lower than Tsat.

This is another solution for cooling a source to be cooled, which proves to be compact. By means of this, a variety of solutions and a variety of heat collection points are obtained.

According to one embodiment, the intermediate housing comprises a second liquid outlet connected to the inlet line of the evaporator assembly.

In this case, there is no specific tapping made on the main line; the liquid supply tapping of the evaporator assembly is made in the intermediate housing, preferably in the lower part and/or close to the liquid inlet.

This provides an optimization of the tappings and of the locations where a sealed joint or a sealed weld must be made.

According to one embodiment, the intermediate housing comprises an internal separation delimiting a distribution chamber upstream of the guide tube.

According to one embodiment, several vapor ejection nozzles coming from one or more evaporator(s) can be provided. This gives the device very good compactness. One same intermediate housing can receive several ejection nozzles.

According to one embodiment, the ejection nozzle is placed downstream of the inlet line of the evaporator. As a result, liquid admission occurs at a lower temperature than the average temperature at the location of bubble condensation further downstream.

This proves more efficient with respect to the bubble evacuation function in certain flow configurations.

According to an alternative embodiment, the ejection nozzle can be placed upstream of the inlet line of the evaporator.

This does not prevent correct operation and makes it possible to meet a certain need for integration or spatial configuration of the equipment to be cooled.

According to one embodiment, the cooling exchanger is placed higher than the intermediate housing. The system can thus benefit from a thermosiphon effect due to gravity.

According to an alternative embodiment, the cooling exchanger is placed lower than the intermediate housing. Capillary pumping assisted by the pump nevertheless allows the desired correct operation without a thermosiphon effect.

According to one embodiment, the reservoir is distributed along the tubes, outside the tubes. The reservoir is thus distributed, without needing to provide a specific reservoir.

According to one embodiment, one or more other intermediate housing(s) can be provided downstream of the first intermediate housing, each other intermediate housing being arranged in series on the main loop circuit.

Several electronic pieces of equipment located at different points along the path of the main loop can thus be cooled. Each intermediate housing comprises at least one vapor ejection nozzle, which contributes to circulation of the liquid in the main loop even if the pump were to stop.

According to one embodiment, several evaporator assemblies (2, 2′) can be provided, arranged as bypasses at substantially the same location on the main loop circuit. This may suit configurations where the hot sources are close to each other. The system thus formed is particularly compact.

According to one embodiment, the rotational speed of the pump is controlled between a minimum rotation threshold and a maximum rotation threshold (rotational speed or equivalent).

The inventors were able to observe that too high a rotational speed and thus too intense a cold liquid flow in the main loop did not provide advantages, and even increased the risk of one of the evaporators losing prime due to total saturation of the reservoir with subcooled liquid for configurations with a large reservoir. According to an example, a pump speed is chosen giving an hourly flow rate of 5 to 15 liters per minute.

According to one embodiment, a cross-section restriction is provided in the main circuit just downstream of the pump discharge. This is favorable to pumping efficiency; a multiplication factor can be obtained relative to the general flow in the main loop circuit. In practice, it is found that the flow passing through the pump in the parallel branch and exiting at the restriction induces a flow 3 to 4 times higher in the main circuit.

The cross-section restriction also makes it possible to avoid a local recirculation that would locally close (back-loop) the parallel branch where the pump is located.

According to one embodiment, the pump is a centrifugal pump with a weight less than 1 kg and the pump fits within a cubic volume of at most 100 mm per side.

A compact and lightweight solution is proposed, fully compatible with an embedded system in a vehicle, including an aeronautical vehicle where weight and occupied volume are particularly critical.

According to one embodiment, the evaporator(s) is/are positioned below the main circuit. As a result, as the evaporator inlet line is downward, if vapor bubbles or non-condensable gas are present at that location, they will be evacuated by naturally rising and joining the main circuit and the expansion vessel reservoir.

According to one embodiment, the working fluid is acetone. This fluid has intrinsic characteristics particularly relevant for a two-phase application with high reliability requirements.

According to another embodiment, the working fluid can be chosen from: isooctane, R133zd-E, R136mzz-Z, ethanol, cyclopentane, a butene-or butane-based fluid, a pentene-based fluid, a butadiene-based fluid, or a toluene-based fluid.

According to one embodiment, the pressure in the fluid circuit is between 2 bar and 5 bar.

According to one embodiment, a first ratio is provided between the mass flow rate of liquid in the main loop and the mass flow rate of vapor exiting the ejection nozzles of the evaporators, and said first ratio is generally between 3.5 and 50.

According to one embodiment, the system is subjected to the gravitational force of the Earth, and the main loop circuit extends in a plane substantially horizontal relative to gravity. The fluid can circulate in the main loop without using a thermosiphon effect, the driving effect in the main circuit being obtained by vapor injections from evaporator(s) and the pump when it operates.

According to one embodiment, a common reservoir connected to the main loop can be provided. The operational conditions of the loop can thus be centrally controlled by controlling the saturation temperature Tsat, and this also provides an expansion vessel role and receipt of liquid coming from the vapor zones of the capillary evaporators; a reservoir function can thus be avoided in each intermediate housing.

According to one embodiment, the cooling exchanger comprises a plurality of sub-channels arranged in parallel. Good heat exchange efficiency is obtained inside the cooling exchanger.

Other aspects, aims, and advantages of the invention will appear upon reading the following description of an embodiment of the invention, given by way of non-limiting example. The invention will also be better understood with reference to the attached drawings wherein:

FIG. 1 is a principle diagram of the system according to a first embodiment of the invention, with two evaporator assemblies in series, each connected to an intermediate housing, and an optional reservoir,

FIG. 2 is a principle diagram of the system according to a second embodiment of the invention, concerning the configuration of the evaporator assembly,

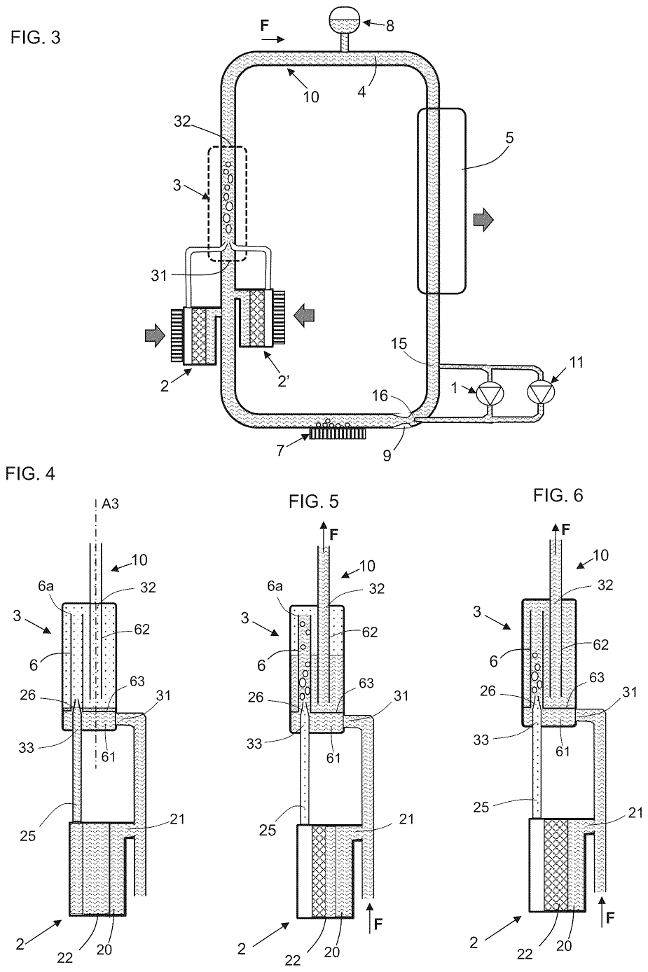

FIG. 3 is a principle diagram of a variant, with two evaporator assemblies connected to the same intermediate housing,

FIG. 4 illustrates a generic example of an intermediate housing receiving a vapor flow from the assembly of an associated evaporator, in a rest configuration, i.e., stopped for a significant time,

FIG. 5 is analogous to FIG. 4 and shows the configuration of the intermediate housing during nominal operation,

FIG. 6 is analogous to FIG. 4 and shows the configuration of the intermediate housing under maximum load and flow conditions,

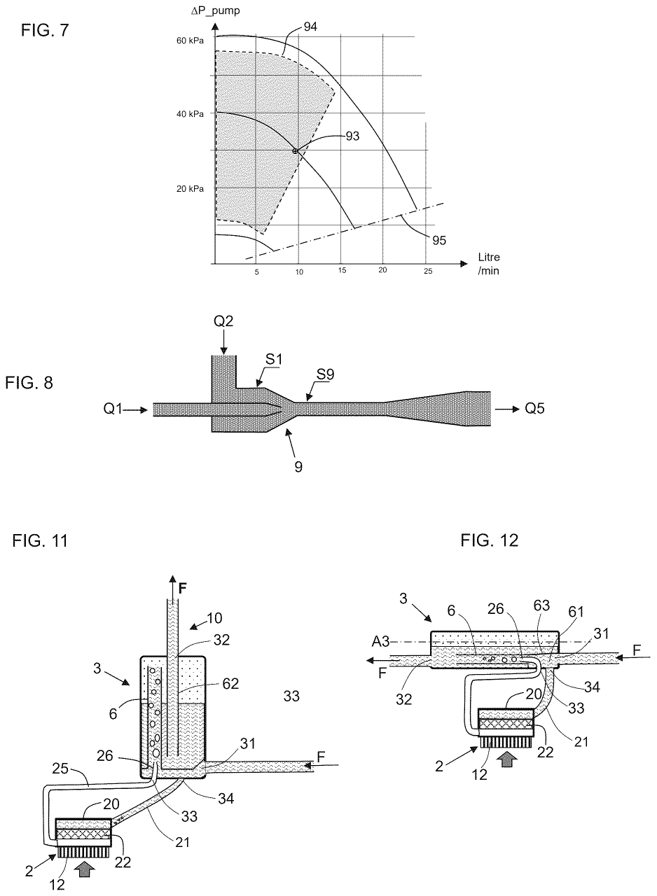

FIG. 7 illustrates a graph concerning pump performance,

FIG. 8 schematically illustrates the operation of the liquid jet pump at the location where the outlet joins the main circuit,

FIG. 9 is analogous to FIG. 2 and illustrates a variant concerning the configuration of the parallel circuit equipped with the pump and the position of the evaporator,

FIG. 10 is analogous to FIG. 2 and illustrates another variant concerning the configuration of the parallel circuit equipped with the pump,

FIG. 11 schematically illustrates a variant of an intermediate housing with 4 ports,

FIG. 12 schematically illustrates a variant of an intermediate housing having a horizontal axis.

In the different figures, the same references designate identical or similar elements.

FIG. 1 shows a heat transfer system 100 using a two-phase working fluid 4 intended to take heat from a hot source 12 and evacuate it at a distance from the hot source. More precisely, the heat transfer system comprises a main loop circuit 10. The heat transfer system contains, in an internal volume hermetically isolated from the outside environment, a given quantity of working fluid 4.

In the present description, “main loop circuit 10” means a pipe or conduit that loops back on itself thus forming a closed circuit for the working fluid 4; it is therefore referred to as a “main conduit” as opposed to other pipes used to connect the evaporators arranged in parallel and as opposed to the parallel branch where the pump is arranged. The main circuit is also called a “thermal bus” and/or “general thermal manifold.”

It is understood that the main circuit generally contains no obstruction element that could hinder free circulation of the working fluid, which circulation occurs in a preferred circulation direction represented by reference F.

Generally, the working fluid is a refrigerant that can be in liquid or vapor phase in the vicinity of the temperatures prevailing in the loop circuit.

According to a particular example, the working fluid 4 is acetone.

According to other examples, the working fluid can be chosen from: isooctane, R133zd-E, R136mzz-Z, ethanol, cyclopentane, a butene-or butane-based fluid, a pentene-based fluid, a butadiene-based fluid, or a toluene-based fluid.

The closed-loop main circuit comprises a predefined quantity of refrigerant fluid. A filling orifice, not shown in the figures, is provided, as well as optionally a purge orifice. The pressure in the fluid circuit is between 2 bar and 5 bar.

Low-pressure fluids are preferably used that cause low flow rates on the main circuit 10.

### Cooling Exchanger

The heat transfer system comprises a cooling exchanger 5.

The cooling exchanger 5 evacuates the heat carried by the main conduit at a distance from the hot source(s) 12. The cooling exchanger 5 is formed by a portion of the main conduit itself and a heat exchanger coupled to a cold source; this heat exchanger is deliberately not detailed here, it can be of any type known in the art, for example, an air exchanger with fins, optionally with forced convection with a fan; it can also be, for example, a liquid exchanger such as a cross-flow exchanger with another liquid, for example, water.

In a typical example of server boards, the heat generated at the processors is evacuated by means of the main circuit, away from the server board, into a conventional water circulation circuit.

According to another example, the cooling exchanger 5 can be used to heat an external element by delivering heat to that external equipment. For example, the cooling exchanger 5 can be used to heat a wing leading edge in an aircraft or an air intake of a turboprop engine.

Advantageously, the cooling exchanger provides subcooling of the liquid, to deliver subcooled liquid. In practice, the subcooled liquid leaving the cooling exchanger is at a temperature 5° C. to 10° C. lower than the saturation temperature Tsat, Tsat being the liquid-vapor equilibrium temperature for the pressure prevailing in the circuit.

The subcooling is sufficient so that the liquid phase in the main circuit remains liquid even in the presence of parasitic thermal leaks. Moreover, this prevents possible cavitation of a pump, which will be discussed later. The advantage of having a main circuit essentially containing liquid is that system operation is only minimally affected by the accelerations to which it is subjected, for example, in a vehicle with changing directions and highly variable intensity, such as an aircraft.

Optionally, the cooling exchanger can comprise a plurality of sub-channels arranged in parallel in order to maximize thermal exchanges.

### Evaporator Assembly(ies)

The heat transfer system comprises one or more evaporator assembly(ies) 2.

Advantageously, to take heat from the hot source 12, an evaporator assembly 2 arranged as a bypass of the main circuit is provided. The evaporator assembly 2 being placed in a parallel configuration of the main circuit does not introduce a pressure loss in the main circuit 10.

The evaporator assembly 2 comprises an inlet line 21, tapping liquid fluid from the main loop, an evaporator 20 including a porous element 22 forming capillary pumping and thermally coupled to a hot source to be cooled, and an outlet line 25.

The outlet line 25 opens into an element called here an “intermediate housing,” which will be described in the following paragraphs. The outlet line 25 comprises at its end an ejection nozzle 26, which injects the fluid in a mainly vapor phase into the intermediate housing.

The structure and functions of the evaporator are not detailed here; the person skilled in the art can refer, for example, to document FR3065279 for various teachings relating to an example evaporator targeted here.

In the case shown in FIG. 1, there are two evaporator assemblies 2, one arranged after the other along the main circuit 10, thus in a “series” configuration. It will be seen later that they can be in a “parallel” configuration. More generally, any hybrid combination, series and parallel, can also operate thanks to the present invention.

In addition to the evaporator assemblies described above, the heat transfer system can also take heat in an alternative way directly from a source to be cooled. As illustrated in FIG. 3, a hot source to be cooled 7 is in conductive thermal contact with a portion of piping of the main circuit. At this location, depending on the thermal power delivered by the hot source to be cooled, a local emulsion occurs on the inner side of the conduit wall. Since operation is in a subcooled regime, with a loop temperature lower than Tsat, the vapor bubbles created at that location are locally condensed without hindering the arrival of liquid to the porous wick.

The proposed heat transfer system can thus combine conventional evaporator systems and systems for taking heat by direct conductive thermal contact.

### Intermediate Housing

The heat transfer system comprises one or more intermediate housing(s) 3 placed in series on the main circuit. Each intermediate housing 3 is associated with one or more evaporator assemblies 2.

As visible in FIG. 4, each intermediate housing 3 is formed as a vessel having at least three ports, namely a liquid inlet 31, a liquid outlet 32, and a vapor inlet 33, the liquid inlet 31 receiving the subcooled liquid coming from the cooling exchanger 5.

When there is a single intermediate housing, as illustrated for example in FIG. 3, the liquid inlet 31 of the intermediate housing receives the subcooled liquid coming from the cooling exchanger and delivers downstream liquid via its liquid outlet 32 toward the cooling exchanger.

When there are several intermediate housings in series as illustrated in FIG. 1, the liquid outlet 32 of the first intermediate housing 3 is directed toward the liquid inlet 31 of the second intermediate housing 3′.

According to the example presented in FIGS. 4 to 6, the intermediate housing 3 has an elongated shape with an axis A3 in the local loop circulation direction.

According to the example, the intermediate housing has a generally cylindrical shape.

According to an example, the outer diameter of the intermediate housing can be between 20 mm and 40 mm. According to an example, the diameter of the main conduit can be between 8 mm and 20 mm. The stated dimensions are not limiting.

According to an option shown in FIG. 11, the intermediate housing 3 comprises a second liquid outlet 34 connected to the inlet line 21 of the evaporator assembly 2.

The ejection nozzle 26 is placed downstream of the inlet line of the evaporator. However, according to an alternative embodiment shown in FIG. 2, the ejection nozzle can be placed upstream of the inlet line of the evaporator (see FIG. 2).

The intermediate housing 3 comprises a guide tube 6 that surrounds the ejection nozzle 26. The guide tube 6 makes it possible to maximize local vapor condensation at the outlet of the ejection nozzle. As illustrated in FIG. 5, the guide tube 6 comprises an open end 6a, which acts as an overflow, i.e., the liquid pushed by the vapor jet overflows over the edge 6a.

It is noted that the interior volume of the guide tube 6 is the site of local condensation of the vapor bubbles ejected by the ejection nozzle 26.

Moreover, an outlet tube 62 is provided in the intermediate housing, which channels the liquid outlet from the interior volume of the intermediate housing 3 to the outlet port 32.

Optionally, several internal guide tubes 6 can be provided in the intermediate housing 3, the tubes extending along the nozzle axis. Each tube is arranged opposite a vapor ejection nozzle 26. An example is illustrated in FIG. 3 where there are 2 outlet nozzles 26 in an intermediate housing 3 and, consequently, there are two respective guide tubes facing them.

The intermediate housing 3 comprises an internal separation 63 delimiting a distribution chamber 61 upstream of the guide tube 6. When the intermediate housing 3 includes only one guide tube 6 for vapor condensation, the distribution chamber acts as a buffer chamber. When the intermediate housing 3 includes several guide tubes 6 in parallel, the distribution chamber 61 acts as a plenum to simultaneously feed in parallel the guide tubes 6 present in the intermediate housing.

It is noted that the design presented here makes it possible to prevent the bubbles generated by vaporization of liquid (ejected by outlet nozzles 26) from leaving the intermediate housing 3. Thus, the general portions of the main loop circuit linking between the intermediate housings and the cooling exchanger remain free of bubbles and are filled only with liquid, with the technical advantages set out above.

In the example of variants illustrated in FIG. 12, the axis A3 of the intermediate housing is horizontal, as opposed to the vertical position illustrated in FIGS. 4 to 6 and 11.

In this horizontal case, the intermediate housing 3 can be without an outlet tube 62, the outlet port 32 being naturally supplied with liquid without risk of having vapor or bubbles at that location.

It is noted that the internal separation 63 can be aligned with a portion of the guide tube 6. It should also be noted that the guide tube can be formed by an elongated deflector, which cooperates with an internal wall of the intermediate housing to together form a constrained passage similar to the guide tube set out above.

According to an option, a specific reservoir 8 arranged at a preferably high position of the main circuit is provided. A heating resistor and a temperature sensor can be provided on this reservoir in order to control, in particular, the start-up phase of the heat transfer device.

According to another solution, the reservoir forming the expansion vessel is formed in each of the intermediate housings. A case is shown in FIG. 6 where the excess volume comes to occupy the entire available internal volume in the intermediate housing 3.

### Pump

The heat transfer system comprises a branch 14 parallel to the main circuit with a pump 1.

A cross-section restriction 9 is provided in the main circuit just downstream of the pump discharge.

As visible in FIG. 8, the section S9 downstream of the liquid ejection nozzle is substantially smaller than the section S1 upstream. With regard to flow rates, Q5 denotes the general flow in the loop, Q1 the flow leaving the branch parallel with the pump. The tapping of the pump branch is not shown in FIG. 8, Q5=Q1+Q2. A value between 0.3 and 0.6×S1 can be chosen for the section S9. Q2 is the flow in the main circuit which does not pass in the pump branch 14.

Thanks to these geometric conditions, a circulation amplification effect can be obtained, namely Q5 is around 3 to 4 times Q1. The power required to drive the pump 1 thus proves particularly moderate.

According to the example illustrated in FIGS. 1 to 2, the pump 1 is fed by subcooled liquid coming from the cooling exchanger 5 (tapping point 15) and discharges further downstream a jet of liquid into the main circuit (discharge point 16), upstream of the intermediate housing 3.

According to a preferred example, the pump 1 is a centrifugal pump. However, other types of pumps, such as gear pumps, can also be adopted.

According to a typical embodiment, the pump 1 has a weight less than 1 kg. According to another embodiment, the weight of the pump can be less than 600 grams.

From the occupied volume point of view, according to an example, the pump 1 fits within a cubic volume of at most 100 mm per side, which is particularly compact. According to a preferred example, the diameter of the pump can be around 80 mm.

FIG. 7 illustrates the sizing of such a pump in flow and pressure. The X-axis shows flow in liters per minute, and the Y-axis shows the pressure difference deltaP between outlet and inlet in kiloPascals. FIG. 7 illustrates three iso-rotation-speed curves, from minimum at the bottom to maximum at the top.

The line referenced 95 illustrates the pump cavitation risk zone. The shaded zone 94 illustrates the ideal operating region for the application. A target operating point 93 is chosen with a flow of around 10 liters per minute for a deltaP of 30 kPa. As soon as the heat transfer system is in service, the pump is controlled at a constant speed corresponding to operating point 93.

According to an option shown in FIG. 3, two pumps 1, 11 in parallel with each other can be provided. Thus, damage on one of the pumps has only a limited impact, and the overall operation is only slightly affected. The unavailability rate of such a heat transfer system can thus be drastically reduced.

According to an alternative configuration illustrated in FIG. 9, the pump is fed by liquid tapped downstream of the cooling exchanger 5 (tapping point 15), and discharges liquid upstream of the cooling exchanger (discharge point 16). According to another possibility, the pump is fed by liquid tapped upstream of the cooling exchanger 5 (tapping point 15), and discharges liquid downstream of the cooling exchanger (discharge point 16).

According to yet another alternative configuration illustrated in FIG. 10, the pump is fed by liquid tapped at an intermediate point 15 between the cooling exchanger and the intermediate housing, and discharges liquid upstream of said intermediate point at point 16.

In the example illustrated in FIGS. 9 and 11, the evaporator(s) is/are positioned below the main circuit. In this case, the evaporator inlet line is downward, and if there are bubbles 29 of vapor or non-condensable gas at that location, they will be evacuated by naturally rising and joining the main circuit and the expansion vessel reservoir.

1. A heat transfer system comprising:
a main circuit in a closed loop, comprising a predefined quantity of refrigerant fluid, with a loop circulation direction,
at least one cooling exchanger, comprising a portion of the main circuit and a heat exchanger coupled to a cold source, to remove heat and subcool liquid, to deliver subcooled liquid,
at least one pump arranged on a branch parallel to the main circuit, to impart a liquid circulation in the main circuit according to the loop circulation direction, with tapping and discharge at respective locations where the refrigerant is in the liquid phase,
at least one intermediate housing placed in series on the main circuit, having at least three ports, namely a liquid inlet, a liquid outlet, and a vapor inlet, the liquid inlet receiving the subcooled liquid coming from the cooling exchanger,
at least one evaporator assembly arranged as a bypass of the main circuit with
at least one inlet line, tapping liquid fluid from the main circuit,
an evaporator including a porous capillary pumping element coupled to a hot source to be cooled, to be the site of a vaporization of the refrigerant fluid,
at least one outlet line having at least one ejection nozzle, which injects the fluid in a mainly vapor phase into the intermediate housing via the vapor inlet according to the loop circulation direction.

2. The heat transfer system according to claim 1, wherein the pump is fed by subcooled liquid coming from the cooling exchanger and discharges further downstream a jet of liquid into the main circuit, upstream of the intermediate housing.

3. The heat transfer system according to claim 1, wherein the intermediate housing comprises an interior volume available to accommodate an excess of liquid, serving as a reservoir and expansion vessel.

4. The heat transfer system according to claim 1, wherein the intermediate housing has an elongated shape with an axis in the local loop circulation direction.

5. The heat transfer system according to claim 4, wherein the intermediate housing has a generally cylindrical shape.

6. The heat transfer system according to claim 4, wherein the intermediate housing comprises a guide tube that surrounds the ejection nozzle.

7. The heat transfer system according to claim 1, wherein the intermediate housing comprises a second liquid outlet connected to the inlet line of the evaporator assembly.

8. The heat transfer system according to claim 1, wherein a cross-section restriction is provided in the main circuit just downstream of the pump discharge.

9. The heat transfer system according to claim 1, wherein the pump is a centrifugal pump with a weight less than 1 kilogram and a volume fitting within a cube of 100 mm per side.

10. The heat transfer system according to claim 1, wherein the working fluid is acetone.
